(19) United States
(12) Patent Application Publication
(10) Pub. No.: US 2026/0286497 A1
(43) Pub. Date: Sep. 24, 2026

(54) FILM MASK FOR OLED DEPOSITION FOR ULTRA-HIGH RESOLUTION

(71) Applicant: HUNETPLUS CO., LTD., Cheonan-si (KR)

(72) Inventors: Hyuk Jin CHA, Seoul (KR); Keun Soo KIM, Daejeon (KR); Eun Ji CHO, Cheonan-si (KR); Byung Yoon JEON, Osan-si (KR); So Hui LEE, Cheonan-si (KR)

(21) Appl. No.: 19/083,629

(22) Filed: Mar. 19, 2025

(51) Int. Cl. C23C 14/04; H10K 71/16

(52) U.S. Cl. CPC C23C 14/042; H10K 71/166

(57) ABSTRACT

A film mask for OLED deposition for ultra high resolution includes a first layer including a polyimide resin material and a second layer including an organic-inorganic composite material. The first and second layers each have deposition holes for deposition of an OLED material. The first layer is formed by: coating the polyimide resin material on a base substrate, and hardening the coated polyimide resin material. The second layer is formed by coating the organic-inorganic composite material on the hardened first layer, exposing the coated organic-inorganic composite material using a photomask, developing the exposed organic-inorganic composite material, and patterning upper deposition holes in the second layer. Subsequently, lower deposition holes are etched in the first layer using the second layer with the upper deposition holes as an etch mask.

### TECHNICAL FIELD

The present disclosure relates to a film mask for OLED deposition for ultra-high resolution and to a method for fabricating the same.

### RELATED ART

There are various types of displays. Recently, however, Organic Lighting Emitting Diode (OLED) displays or organic Electro Luminescence (EL) displays are leading the market.

OLED displays that are manufactured by vacuum deposition are mostly manufactured using metallic fine metal masks (FMM). In particular, EMMs are usually used for large-area deposition marks using invar, which is an alloy having heat resistance.

However, as high resolution displays become more prevalent, there is an increasing need for deposition masks with higher resolution. However, EMMs pose challenges due to their limitations on further increasing resolutions and relatively heavy weight.

Further, demands for augmented reality (AR) or virtual reality (VR) are expected to surge as a high value-added industry, and in order to prepare for this, there is a need for deposition masks that can be implemented for ultra high-resolution displays over at least 3000 ppi.

Meanwhile, as an attempt to implement ultra high-resolution displays, a resin mask including a metal layer such as the one disclosed in “method of manufacturing a deposition mask and method of manufacturing an organic semiconductor element” (Japanese Patent Application Publication No. 2013-165058) has been proposed. However, in JP 2013-165058, a machining process that emits laser to form a deposition hole opening pattern is used, and most patent documents in the related art adopt this method. However, laser patterning generates burrs at openings or faces challenges in controlling the laser, so there is a problem of poor manufacturability.

### SUMMARY

The present disclosure has been made in an effort to satisfy the necessity described above and overcome the problems described above. A first objective of the present disclosure is to provide a film mask for OLED deposition for ultra high resolution that is light-weight and has mechanical stability and heat resistance required in deposition processes in order to implement a deposition mask that enables ultra high-resolution patterning.

A second objective of the present disclosure is to provide a disposable-type film mask for OLED deposition for ultra high resolution. A film mask for OLED deposition of the present disclosure can be used as a wafer-based mask for AR and VR equipment and a mask for OLED and QDOLED deposition mask of 4G-10G.

A third objective of the present disclosure is to provide a film mask for OLED deposition for ultra high resolution that can perform dry etch even without an additional mask in the processes by using a film mask configuration as a necessary configuration in a manufacturing process and that can solve problems of laser patterning of the related art through such a new manufacturing process.

According to an aspect of the present disclosure, a film mask for OLED deposition for ultra high resolution may include a first layer including a polyimide resin material; a second layer disposed on the first layer and including an organic-inorganic composite material; and a frame layer disposed on the second layer along a peripheral edge thereof. Each of the first layer and the second layer may have deposition holes for deposition of an OLED material therethrough. The first layer may be formed by a first process, which includes coating the polyimide resin material on a base substrate, and hardening the coated polyimide resin material. The second layer may be formed by a second process, which includes coating the organic-inorganic composite material on the hardened first layer, exposing the coated organic-inorganic composite material to light having a predetermined wavelength through a photomask, developing the exposed organic-inorganic composite material, and a first patterning step of forming upper deposition holes that correspond to patterning holes of the photomask. Further, the formation of the first layer may be completed with a second patterning step of etching lower deposition holes using the second layer with the upper deposition holes as an etch mask after the first process and the second process.

The polyimide resin material may be poly amic acid, and said step of hardening may include a first heat treatment step of imidizing the poly amic acid into polyimide via a first heat treatment and a second heat treatment step of crystallizing the imidized polyimide via a second heat treatment.

The organic-inorganic composite material may include a silicon photoresist containing an organic material. The silicon photoresist may be poly imidesiloxane containing imide and siloxane.

The second patterning step may include dry etching on the first layer. The dry etching may provide an etch selectivity of at least 2:1 in favor of the first layer compared to the second layer.

The second layer may have a greater coefficient of thermal expansion (CTE) than the first layer, and the first layer may have a greater elastic modulus than the second layer.

The material of the frame layer may be glass.

One or more alignment marks may be formed on the top surface of the second layer or the top surface of a magnetic layer disposed on the second layer for alignment with a deposition target substrate.

The alignment marks may be recognizable based on a difference in at least one of light transmittance, refractive index, or thickness with respect to the first layer. A difference in light transmittance between the first layer and the second layer may be 10% or more. A difference in refractive index between the first layer and the second layer may be 0.05 or more.

Meanwhile, the film mask for OLED deposition for ultra high resolution may further include a magnetic layer on or in the second layer, and the magnetic layer may be formed of magnetic powder or a metal layer.

According to another aspect of the present disclosure, a method for forming a film mask for OLED deposition for ultra high resolution may include coating a base substrate with a polyimide resin material, thereby forming a first layer; hardening the polyimide resin material; coating the first layer with an organic-inorganic composite material, thereby forming a second layer; exposing the organic-inorganic composite material to light having a predetermined wavelength using a photomask; developing the organic-inorganic composite material; patterning upper deposition holes in the second layer, the upper deposition holes corresponding to patterning holes of the photomask; and etching lower deposition holes in the first layer using the second layer with the upper deposition holes as an etch mask.

The polyimide resin material may be poly amic acid, and said step of hardening the polyimide resin material may include imidizing the poly amic acid into polyimide via a first heat treatment; and crystallizing the polyimide via a second heat treatment.

The organic-inorganic composite material may include a silicon photoresist containing an organic material. The silicon photoresist may be poly imidesiloxane containing imide and siloxane.

Said step of etching the first layer may be performed by dry etching, and the dry etching may provide an etch selectivity of 2:1 or higher in favor of the first layer over the second layer.

The second layer may have a greater coefficient of thermal expansion than the first layer, and the first layer may have a greater elastic modulus than the second layer.

The method may further include forming a magnetic layer on or in the second layer, the magnetic layer being formed of magnetic power or a metal layer.

The method may further include forming one or more alignment marks on the second layer. The alignment marks may be recognizable based on a difference in at least one of light transmittance, refractive index, or thickness with respect to the first layer.

A difference in light transmittance between the first layer and the second layer may be 10% or more.

A difference in refractive index between the first layer and the second layer may be 0.05 or more.

According to embodiments of the present disclosure, as a deposition mask that enables ultra high-resolution patterning, a film mask for OLED deposition for implementing ultra high resolution that is light-weight and has mechanical stability and heat resistance required in deposition processes can be provided.

Further, since a disposable type of film mask for OLED deposition for implementing ultra high resolution is provided, it is possible to reduce the process costs and decrease the process time.

Further, it is possible to perform dry etch during the processes even without an additional separate mask by using a film mask configuration as a necessary configuration in a manufacturing process, and it is possible to overcome problems of laser patterning of the related art.

### BRIEF DESCRIPTION OF THE DRAWINGS

FIG. 1 is a plan view showing a top view of a film mask for OLED deposition for ultra-high deposition according to an embodiment of the present disclosure.

FIG. 2 is a cross-sectional view showing a cross-section taken along line A-A in the embodiment shown in FIG. 1.

FIG. 3 is a flow chart describing the manufacturing process of OLED devices for ultra-high resolution using a film mask according to an embodiment of the present disclosure.

### DETAILED DESCRIPTION

Hereafter, exemplary embodiments of the present disclosure will be described in detail with reference to the accompanying drawings and the matters in the drawings, but the present disclosure is not limited or restricted to the exemplary embodiments.

The embodiments to be described below may be modified in various ways. The embodiments to be described below do not limit the present disclosure. All modifications, equivalents, and substitutions should be understood to be included in the scope of the present disclosure.

In the following description of the present disclosure, detailed descriptions of well-known functions or configurations relating to the present disclosure will not be provided so as not to obscure the description of the present disclosure. Terminologies are used in the specification to appropriately express embodiments of the present disclosure and may be understood in accordance with users, intention of operators, or customs in the field. Therefore, the definitions of the terminologies should be construed based on the contents throughout the specification.

### Film Mask for OLED Deposition for Ultra High Resolution

An embodiment of a film mask for OLED deposition for ultra high resolution may include a first layer made of a polyimide resin material, a second layer that is a thin layer made of an organic-inorganic composite material on the first layer, and a frame layer stacked at the edge on the second layer. The first and second layers may each have deposition holes configured for deposition of an OLED material. The first layer may be formed through a first process including a step of coating a polyimide resin material on a base substrate (S110) and a step of hardening the coated polyimide resin material (120). The second layer may be formed through a second process including a step of coating an organic-inorganic composite material on the hardened first layer (S210), a step of exposing the coated organic-inorganic composite material using a photomask (S220), a step of developing the exposed organic-inorganic composite material (S230), and a first patterning step of forming upper deposition holes corresponding to patterning holes of the photomask (S240). Further, the first layer may be formed through a second patterning step of etching lower deposition holes using the second layer with the upper deposition holes as an etch mask (S310) after the first and second processes. In Step S220, the coated organic-inorganic composite material may be exposed to light having a predetermined wavelength through the photomask. In some embodiments, the predetermined wavelength may correspond to ultraviolet (UV), deep ultraviolet (DUV), or extreme ultraviolet (EUV). By way of example, about 200-400 nm for the general UV range, about 100-300 nm for the DUV range, and about 10-150 nm for the EUV range.

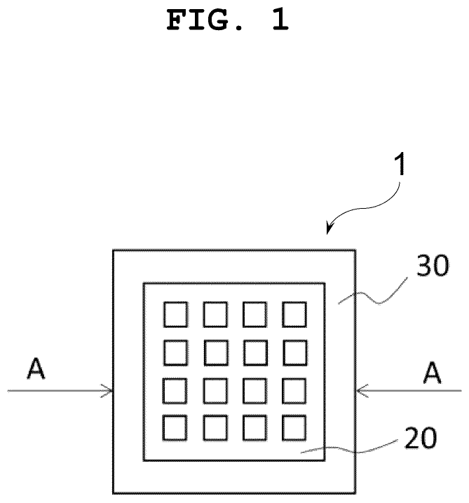

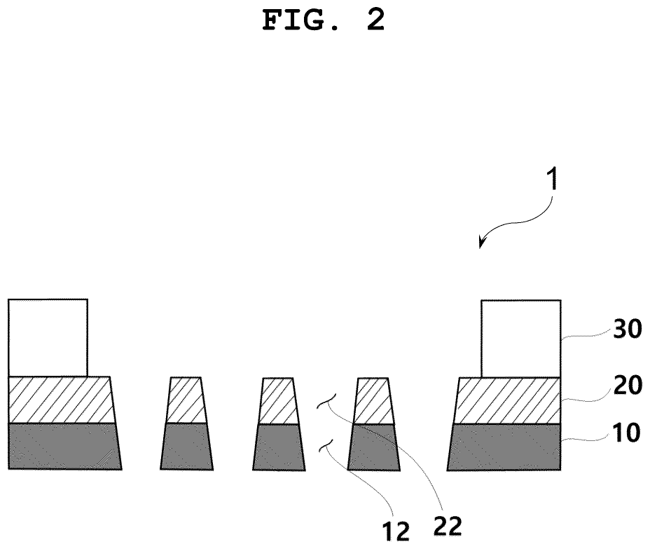

Hereafter, an embodiment of the present disclosure is described in detail with reference to FIGS. 1 and 2.

The film mask 1 according to the present disclosure may include a first layer 10, a second layer 20, and a frame 30. Upper deposition holes 22 of the second layer 20 and lower deposition holes 12 of the first layer 10 may be connected to each other to allow an evaporated deposition substrate to be deposited with ultra high resolution on a substrate without a shadow effect in the deposition process. The fine metal masks (FMM) of the related art have a large weight and the limitation of processibility, i.e., small thickness cannot be implemented, so the present disclosure provides a film type mask for implementing ultra high resolution (over 3000 ppi). An embodiment of the present disclosure provides a structure of a film type mask together with first, second, and third processes. This is because the structure of the film mask 1 of the embodiment may be incorporated in the manufacturing process and the necessary configuration of the present disclosure may be formed along with the manufacturing process.

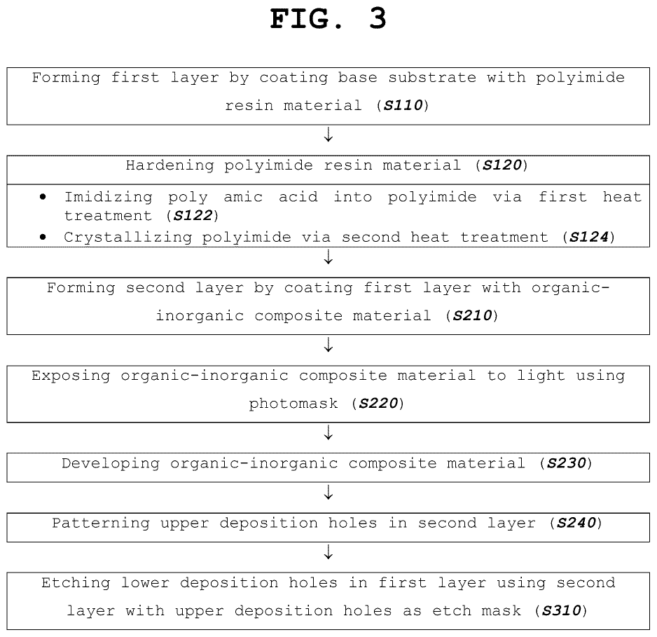

Referring to FIG. 3, the manufacturing process of the film mask 1 may be sequentially performed through a first process, a second process, and a third process. A first layer 10 hardened though the first process may exhibit excellent mechanical strength and heat resistance. Though will be described below, the thermosetting process of two times may reduce the coefficient of thermal expansion of the film mask 1, thereby allowing a shape stability to be maintained even in a high-temperature environment for deposition. The second layer 20 formed through the second process may include the first patterning process (S240) of forming upper deposition holes 22 through a photolithography process, but common photoresist or photo-sensitive polyimide (PSPI) may not be used for the second layer 20 for this purpose. PSPI is materially similar to the first layer 10 at the lower portion, so the second patterning step (S310) to be described below may become more difficult to be performed, and it may be undesirable as a mask. As a result, the upper deposition holes 22 may be formed in the second layer 20 using a photomask in the first patterning step (S240) and then the second layer 20 with the upper deposition holes 22 may be used as an etch mask for patterning the first layer 10. As such, an organic-inorganic composite material may be used as a suitable material. The organic-inorganic composite material will be described below.

The polyimide resin material may be poly amic acid in the first process, and the hardening process (S120) may include a first heat treatment step (imidization) of imidizing poly amic acid into polyimide through heat treatment (S122) and a second heat treatment step (crystallization) of crystallizing the imidized polyimide through heat treatment (S124). In the second process, the organic-inorganic composite material may be silicon photoresist containing organic materials.

The silicon photoresist may be poly imidesiloxane containing imide and siloxane.

In general, a polyimide (PI) film is formed by making a polyimide resin material into a film, and a polyimide resin material refers to a resin with a high heat resistance that is produced by manufacturing a polyamic acid derivative through solution polymerization of aromatic dianhydride with aromatic diamine or aromatic diisocyanate and then imidizing it by ring closure dehydration at a high temperature.

Since such a polyimide film has excellent mechanical properties, heat resistance, and electrical insulation, it is used in various fields for electrical materials such as the insulating film of a semiconductor, an electrode protective film of a TFT-LCD, and a substrate for a flexible printed circuit.

In particular, in the embodiment of the present disclosure, since heat treatment is performed for several minutes at about 400-450 degrees (under a nitrogen environment) in the second heat treatment step (S124), amorphous crystallization can occur, and the coefficient of thermal expansion (CTE) can be further decreased.

The silicon photoresist that forms the second layer 20 in the embodiment may be poly imidesiloxane, which includes siloxane as the primary structure and includes imide. Accordingly, the second layer 20 may be designed to have similarity in the polymer structure to crystallized polyimide of the first layer 10. This configuration may contribute to increasing not only the bonding force between the first layer 10 and the second layer 20, but the elastic modulus of the first-second composite layer. Further, in terms of coefficient of thermal expansion (CTE), it was found that even though there is a difference of coefficients of thermal expansion between the first layer 10 having relatively a lower coefficient of thermal expansion and the second layer 20 having a relatively higher coefficient of thermal expansion, there is no separating or bending therebetween when the temperature is increased. This suggests that intermolecular cross-packing of the polyimide of the first layer 10 follows or is influenced by the poly imidesiloxane of the second layer 20.

It is preferable that the second patterning step (S310) performs dry etching on the first layer 10 with an etch selectivity (e.g., etching selection ratio) two times or higher over the second layer 20. When the etching selection ratio is lower than 2:1, the second layer 20 may be depleted before the etching of the first layer 10 is completed, which may increase the size of the deposition hole pattern formed already, potentially posing a difficulty to manufacture a high-resolution mask. Further, if the thickness of the first layer 10 is decreased to overcome a low etching selection ratio, there may be a problem that the physical strength is deteriorated and there is a risk of damage during the processes.

The photoresist that constitutes the second layer 20 may serve as a layer that determines the resolution of the film mask 1 for deposition. Therefore, the smaller the thickness becomes, the smaller the pattern can be formed, and it is preferable to form the second layer 20 with a minimal thickness in order to implement higher resolutions.

Further, since the etching selection ratio between the first layer 10 and the second layer 20 may determine the thickness of the final first-second composite layer, it is preferable to perform coating with a thickness greater than the final thickness in the first process even with considering the function of the etching mask of the second layer.

Accordingly, it is preferable to perform dry etching with an etching selection ratio between 2:1 and 6:1 in favor of the first layer 10 over the second layer 20. An etching selection ratio exceeding six times may cause non-uniformity of an etching source such as positive ion or radical, depending on the complexity of patterns.

Etching selection ratios of the first layer 10 and the second layer 20 over time are provided in Table 1 as an experimental example according to the embodiment. In this case, reactive ion etching (RIE) was used as the dry etching technique, but chemical etching (plasma radical etching) may also be possible as long as the chemical etching process meets the etching selection ratio requirements. In the experimental example, the etching ratio of the first layer 10 and the second layer 20 was selected to be about 4.7:1.

TABLE 1

| | First layer | Second layer |
|---|---|---|
| 5 min | 3.182 μm [symbol] 2.542 μm | 2.211 μm [symbol] 2.056 μm |
| | ↓ 0.64 μm | |
| 10 min | 3.176 μm [symbol] 1.853 μm | 2.178 μm [symbol] 1.973 μm |
| | ↓ 1.323 μm | ↓ 0.205 μm |
| 15 min | 3.187 μm [symbol] 1.340 μm | 2.283 μm [symbol] 1.839 μm |
| | ↓ 1.847 μm | ↓ 0.444 μm |
| 20 min | 3.184 μm [symbol] 0.897 μm | 2.329 μm [symbol] 1.801 μm |
| | ↓ 2.287 μm | ↓ 0.528 μm |
| Average | 0.12 | 0.026 |
| etching rate | | |
| (μm/min) | | |

The second layer 20 may exhibit a greater coefficient of thermal expansion (CTE) than the first layer 10, and the first layer 10 may exhibit a greater elastic modulus than the second layer 20.

The polyimide of the first layer 10 may be a material having a heat resistance and a coefficient of thermal expansion (CTE) as low as 1-10 ppm/K. In contrast, the second layer 20 may have a coefficient of thermal expansion (CTE) as high as 1-30 ppm/K. Since the coefficient of thermal expansion of the second layer 20 is higher than the coefficient of thermal expansion of the first layer 10, and the elastic modulus of the second layer 20 is lower than that of the first layer 10, the shape stability and mechanical stability of the second layer 20 may be relatively low. However, while the poly imidesiloxane of the second layer 20 that has a higher coefficient of thermal expansion than the first layer 10 is a brittle material including a photosensitive functional group, the second layer 20 may be strongly bonded to the first layer 10 due to the similarity of its chemical structure with the polyimide of the first layer 10. Accordingly, the second layer 20 may mimic the excellent physical/shape properties of the first layer 10. Further, the second layer 20 may have a photosensitivity and implement a higher etching selection ratio compared to the first layer 10, allowing it to function as an etching mask.

It was found that the elastic modulus of the first-second composite layer decreases in comparison to the first layer 10 alone, but the decrease is not substantial. This may be due to the strong bonding force induced by the double heat processes during the first, second, and third processes and the structural similarity between the first layer 10 and the second layer 20. This hypothesis was confirmed by measuring Young's Modulus of each layer and the composite layer.

The frame 30 may be made of glass. The frame 30 may be stacked along the outer edges of the patterns of the first layer 10 and the second layer 20. The frame 30 may provide convenience in carrying and mounting of the film mask 1 and may minimize mechanical and thermal deformation of the first layer 10 and the second layer 20.

In some embodiments, the film mask 1 for OLED deposition for ultra high resolution may further include a magnetic layer disposed on or within the second layer 20, and the magnetic layer may be formed of magnetic powder or a metal layer. The magnetic layer on the second layer 20 may be implemented as a resin layer or a metal layer mixed with magnetic powder so that the composite layer of the first layer 10 and the second layer 20 can be disposed in close contact with a deposition target substrate by magnetism.

In some embodiments, an align mark (or an alignment mark) may be included on the second layer 20 or the magnetic layer disposed on the second layer 20 for alignment with a deposition target substrate. The alignment mark may be visually recognized by the difference in light transmittance between transparent and opaque regions. Accordingly, the alignment mark may generate a difference in light transmittance in contrast with the composite layer of the first and second layers or the magnetic layer, so it may be formed transparent or opaque.

However, the alignment mark is not limited to relying on light transmittance and may be formed to be distinguished based on a difference from the first layer 10 in terms of a refractive index or a thickness. For better positioning, precision, and uniformity, it is preferable that a difference in light transmittance is 10% or more and a difference in refractive index 0.05 or more. It is preferable that the thickness difference with respect to the first layer 10 at the alignment mark of the second layer 20 is 0.1 μm to 10 μm in consideration of the pattern of the alignment mark formed on the second layer 20.

Although an exemplary embodiment of the present disclosure was described above with reference to the accompanying drawings, those skilled in the art would understand that the present disclosure may be implemented in various ways without changing the necessary features or the spirit of the prevent disclosure. Therefore, the embodiments described above are merely examples and should not be construed as limiting in any respects. Further, all of modifications and changes derived from the meaning and scope of the claims and their equivalent concepts should be construed as being included in the aspect of the present disclosure.

### DESCRIPTION OF REFERENCE NUMERALS

1: film mask
10: first layer
12: upper deposition holes
20: second layer
22: lower deposition holes
30: frame

What is claimed is:

1. A film mask for OLED deposition for ultra high resolution, the film mask comprising:
a first layer including a polyimide resin material;
a second layer disposed on the first layer and including an organic-inorganic composite material; and
a frame layer disposed on the second layer along a peripheral edge thereof,
wherein each of the first layer and the second layer has deposition holes for deposition of an OLED material therethrough,
wherein the first layer is formed by a first process comprising:
coating the polyimide resin material on a base substrate; and
hardening the coated polyimide resin material,
wherein the second layer is formed by a second process comprising:
coating the organic-inorganic composite material on the hardened first layer;
exposing the coated organic-inorganic composite material using a photomask;
developing the exposed organic-inorganic composite material; and
a first patterning step of forming upper deposition holes that correspond to patterning holes of the photomask, and
wherein lower deposition holes are formed by a second patterning step of etching the first layer using the second layer with the upper deposition holes as an etch mask after the first process and the second process.

2. The film mask of claim 1, wherein the polyimide resin material is poly amic acid, and said step of hardening includes:
imidizing the poly amic acid into polyimide via heat treatment, which serves a first heat treatment step; and
crystallizing the imidized polyimide via heat treatment, which serves a second heat treatment step.

3. The film mask of claim 1, wherein the organic-inorganic composite material includes a silicon photoresist containing an organic material.

4. The film mask of claim 3, wherein the silicon photoresist is poly imidesiloxane containing imide and siloxane.

5. The film mask of claim 1, wherein the second patterning step includes dry etching on the first layer, and
wherein during the dry etching, an etch selectivity for the first layer compared to the second layer is at least 2:1.

6. The film mask of claim 1, wherein the second layer has a greater coefficient of thermal expansion (CTE) than the first layer, and
wherein the first layer has a greater elastic modulus than the second layer.

7. The film mask of claim 1, further comprising a magnetic layer formed on or in the second layer,
wherein the magnetic layer formed of magnetic powder or a metal layer.

8. The film mask of claim 1, wherein an alignment mark is formed on the second layer, the alignment mark being recognizable based on a difference in at least one of light transmittance, refractive index, or thickness with respect to the first layer.

9. The film mask of claim 8, wherein a difference in light transmittance between the first layer and the second layer is 10% or more.

10. The film mask of claim 8, wherein a difference in refractive index between the first layer and the second layer is 0.05 or more.

11. A method for forming a film mask for OLED deposition for ultra high resolution, comprising:
coating a base substrate with a polyimide resin material, thereby forming a first layer;
hardening the polyimide resin material;
coating the first layer with an organic-inorganic composite material, thereby forming a second layer;
exposing the organic-inorganic composite material to light having a predetermined wavelength using a photomask;
developing the organic-inorganic composite material;
patterning upper deposition holes in the second layer, the upper deposition holes corresponding to patterning holes of the photomask; and
etching lower deposition holes in the first layer using the second layer with the upper deposition holes as an etch mask.

12. The method of claim 11, wherein the polyimide resin material is poly amic acid, and
wherein said step of hardening the polyimide resin material includes:
imidizing the poly amic acid into polyimide via a first heat treatment; and
crystallizing the polyimide via a second heat treatment.

13. The method of claim 11, wherein the organic-inorganic composite material includes a silicon photoresist containing an organic material.

14. The method of claim 13, wherein the silicon photoresist is poly imidesiloxane containing imide and siloxane.

15. The method of claim 11, wherein said step of etching the first layer is performed by dry etching, and
wherein during the dry etching, an etch selectivity for the first layer compared to the second layer is at least 2:1.

16. The method of claim 1, wherein the second layer has a greater coefficient of thermal expansion than the first layer, and
wherein the first layer has a greater elastic modulus than the second layer.

17. The method of claim 1 further comprising:
forming a magnetic layer on or in the second layer, the magnetic layer being formed of magnetic power or a metal layer.

18. The method of claim 1, further comprising;
forming one or more alignment marks on the second layer,
wherein the alignment marks are recognizable based on a difference in at least one of light transmittance, refractive index, or thickness with respect to the first layer.

19. The method of claim 18, wherein a difference in light transmittance between the first layer and the second layer is 10% or more.

20. The method of claim 18, wherein a difference in refractive index between the first layer and the second layer is 0.05 or more.
